(19) United States
(12) Patent Application Publication
(10) Pub. No.: US 2011/0254111 A1
(43) Pub. Date: Oct. 20, 2011

(54) PACKAGED ACOUSTIC TRANSDUCER DEVICE WITH SHIELDING FROM ELECTROMAGNETIC INTERFERENCE

(75) Inventors: Timothy LECLAIR, Longmont, CO (US); Steve MARTIN, Fort Collins, CO (US)

(73) Assignee: Avago Technologies Wireless IP (Singapore) Pte. Ltd, Singapore (SG)

(21) Appl. No.: 12/762,654

(22) Filed: Apr. 19, 2010

(51) Int. Cl. H01L 29/84

(52) U.S. Cl. 257/416; 257/E29.324

(57) ABSTRACT

A device includes: a housing structure; lid configured together with the housing structure to define a cavity therein; and at least one acoustic transducer disposed within the cavity, wherein the lid shields the at least one acoustic transducer from exposure to electromagnetic interference from electromagnetic radiation originating outside the device. In some embodiments, the housing structure includes some electrically conductive leads, including a ground lead, and the lid is directly connected to the ground lead.

### BACKGROUND

Small acoustic devices, including acoustic transducers, are being employed in a number of applications, including gas flow detectors, and structural flaw detectors for buildings, bridges, pressure piping. In some applications, an acoustic transducer only transmits acoustic signals. In other applications, an acoustic transducer only receives acoustic signals. In still other applications, an acoustic transducer transmits acoustic signals and receives acoustic signals. Generally, acoustic transducers convert received electrical signals to acoustic signals when operating in a transmit mode, and/or convert received acoustic signals to electrical signals when operating in a receive mode. In particular, in many devices and applications, the acoustic signal that is transmitted and/or received is an ultrasonic signal.

Acoustic transducers are manufactured using a variety of different technologies, including piezoelectric ultrasonic transducers and microelectromechanical system (MEMS) transducers. In the past, acoustic transducers have been manufactured with processes where the acoustic transducer element is placed in a metal, ceramic, or plastic package and a lid is bonded to the package. In a typical configuration, an electrical signal produced by the acoustic transducer is provided through a lead or wire from the package to an external amplifier provided on an external circuit board to which the packaged acoustic transducer is attached or connected.

However, there is a continuing need for improved packages for acoustic devices to address specific requirements of various environments in which they are employed.

What is needed, therefore, is an acoustic device having a package that can provide beneficial characteristics for various environments where the packaged acoustic device is deployed.

### SUMMARY

In an example embodiment a device comprises: an electrically conductive lead frame having an aperture therethrough, the electrically conductive lead frame including a plurality of leads including at least one ground lead configured to be connected to an electrical ground; a semiconductor die including at least one acoustic transducer disposed above the aperture in the electrically conductive lead frame, the at least one acoustic transducer being configured to convert between acoustic energy and an electrical signal; an acoustic horn integrally connected to the lead frame, the horn extending from the lead frame and comprising a throat positioned adjacent to the acoustic transducer and a mouth opening at an opposite end of the acoustic horn from the throat; an electrically conductive and acoustically transmissive screen disposed over the mouth of the acoustic horn; and an electrically conductive lid configured together with the base portion of the housing to define a cavity, wherein the acoustic transducer is positioned within the cavity, and wherein the electrically conductive lid is directly connected to the ground lead.

In another example embodiment a device includes: a housing structure including having a base portion integrated with a plurality of electrically conductive leads including at least one ground lead, the housing structure including an aperture extending through a first side thereof; an electrically conductive lid configured together with the housing structure to define a cavity therein; and at least one acoustic transducer disposed within the cavity and disposed above the aperture in the housing structure, wherein the electrically conductive lid is directly connected to the ground lead.

In yet another example embodiment, a device comprises: a housing structure including having a base portion integrated with a plurality of electrically conductive leads including at least one ground lead, the housing structure including an aperture extending through a first side thereof; an electrically conductive lid configured together with the housing structure to define a cavity therein; and at least one acoustic transducer disposed within the cavity and disposed above the aperture in the housing structure, wherein the electrically conductive lid is directly connected to the ground lead.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions shown in the drawings may be arbitrarily increased or decreased for clarity of discussion. Wherever applicable and practical, like reference numerals refer to like elements.

FIG. 1 shows one embodiment of a semiconductor die including an acoustic device.

FIG. 2 shows one embodiment of a semiconductor die including a plurality of acoustic devices.

FIG. 3 shows another embodiment of a semiconductor die including a plurality of acoustic devices.

FIG. 4 shows a top cutaway view of one embodiment of a packaged acoustic device.

FIG. 5 shows a side view of a portion of one embodiment of a packaged acoustic device.

FIG. 6A shows a side cutaway view of another embodiment of a packaged acoustic device.

FIG. 6B shows a first side view of the packaged acoustic device of FIG. 6A.

FIG. 6C shows a top view of the packaged acoustic device of FIGS. 6A-B.

FIG. 6D shows a second side view of the packaged acoustic device of FIGS. 6A-C

FIG. 7 shows a perspective view of one embodiment of a packaged acoustic device.

FIGS. 8A-F illustrate various stages in one embodiment of a process of manufacturing one embodiment of a packaged acoustic device.

### DETAILED DESCRIPTION

In the following detailed description, for purposes of explanation and not limitation, example embodiments disclosing specific details are set forth in order to provide a thorough understanding of an embodiment according to the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparati and methods may be omitted so as to not obscure the description of the example embodiments. Such methods and apparati are clearly within the scope of the present teachings.

Unless otherwise noted, when a first device is said to be connected to a second device, this encompasses cases where one or more intermediate devices may be employed to connect the two devices to each other. However, when a first device is said to be directly connected to a second device, this encompasses only cases where the two devices are connected to each other without any intermediate or intervening devices. Similarly, when a signal is said to be coupled to a device, this encompasses cases where one or more intermediate devices may be employed to couple the signal to the device. However, when a signal is said to be directly coupled to a device, this encompasses only cases where the signal is directly coupled to the device without any intermediate or intervening devices. As used herein, “approximately” means within 10%, and “substantially” means at least 75%. As used herein, when a first structure, material, or layer is said to cover a second structure, material, or layer, this includes cases where the first structure, material, or layer substantially or completely encases or surrounds the second structure, material or layer.

The inventors have recognized that there are a number of factors that can affect the performance of a packaged acoustic device in different applications.

One factor whose importance has been appreciated by the inventors have is the acoustic loss of the package. U.S. patent application Ser. No. 12/619,963, filed on 17 Nov. 2009 in the names of Timothy LeClair et al., discloses a packaged acoustic device which can provide a low acoustic loss. U.S. patent application Ser. No. 12/619,963 is incorporated herein by reference for all purposes as if fully set forth herein.

Another factor that can present itself in some applications is electrical signal loss in the leads or conductors between the packaged acoustic transducer device and an electrical device (e.g., an amplifier) to which the device is connected, particularly when the acoustic transducer device is operating in a receive mode and is transmitting its received signal to a receiver amplifier. U.S. patent application Ser. No. 12/710,636, filed on 23 Feb. 2010 in the names of Timothy LeClair et al., discloses a packaged acoustic device in which an electronic device (e/g., an amplifier) is included in the same package as the acoustic transducer. U.S. patent application Ser. No. 12/619,963 is incorporated herein by reference for all purposes as if fully set forth herein.

The inventors have also appreciated that in some applications, a packaged acoustic transducer can be exposed to externally-generated electromagnetic radiation that can interfere with the proper operation of the acoustic transducer. Such electromagnetic interference (EMI) can cause signal integrity issues for the packaged acoustic device. For example, consider a system where a first packaged acoustic transducer device transmits an acoustic signal at a resonant frequency which is detected by a first packaged acoustic transducer device to measure or control some operating characteristic of a system. In particular, under some circumstances EMI can disturb the resonant frequency of one or both the acoustic resonators, thereby causing the first (transmit) acoustic resonator to operate at a different resonant frequency than the second (receive) acoustic resonator, thereby degrading the overall performance.

With an appreciation of these factors, the inventors have provided an acoustic transducer in various embodiments can achieve desired performance in various operating environments, and particularly in the presence of EMI.

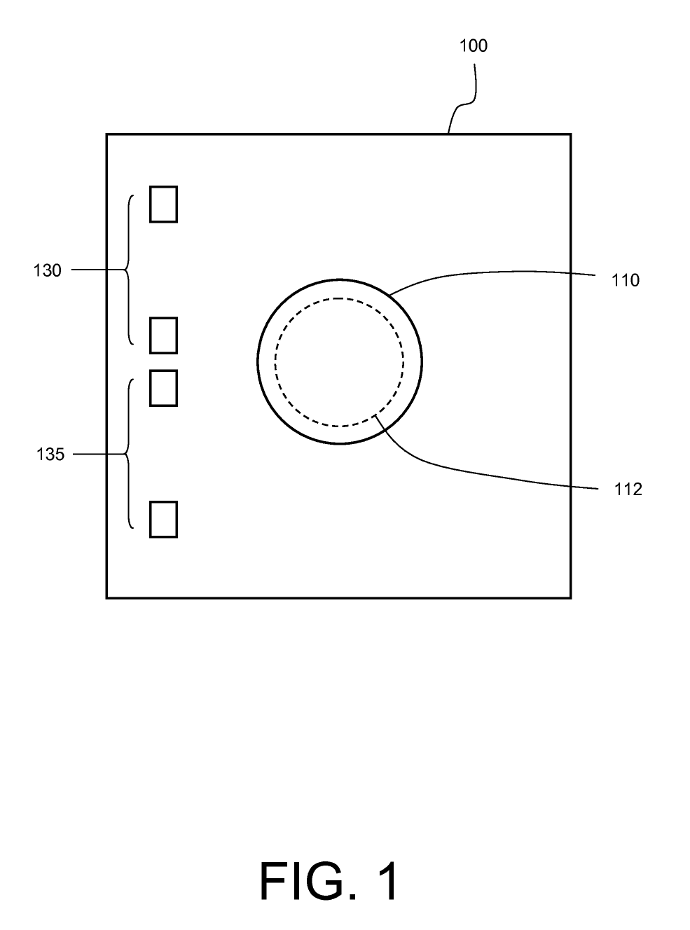

FIG. 1 shows one embodiment of a semiconductor die 100 including an acoustic device 110. Semiconductor die also includes first electrode pads 130 connected to a first electrode of acoustic device 110, and second electrode pads 135 connected to a second electrode of acoustic device 110. In a beneficial embodiment, acoustic device 110 is a microelectromechanical system (MEMS) acoustic transducer having a diaphragm or membrane structure. A through-hole 112 is provided beneath the diaphragm of acoustic device 110.

For illustration purposes only, in one embodiment semiconductor die 100 has dimensions of approximately 2 mm on each side, the diaphragm of acoustic device 110 has a diameter of 540-743 μm, and through hole 112 has a diameter of 410-613 μm.

Operationally, in some embodiments, acoustic device 110 may operate as a transmitting acoustic transducer to receive an electrical signal and to produce therefrom a corresponding acoustic signal or wave which is transmitted. In other embodiments, acoustic device 110 may operate as a receiving acoustic transducer to receive an acoustic signal or wave and to produce therefrom a corresponding electrical signal which is received. In still other embodiments, acoustic device may operate as both a transmitting acoustic transducer and a receiving acoustic transducer.

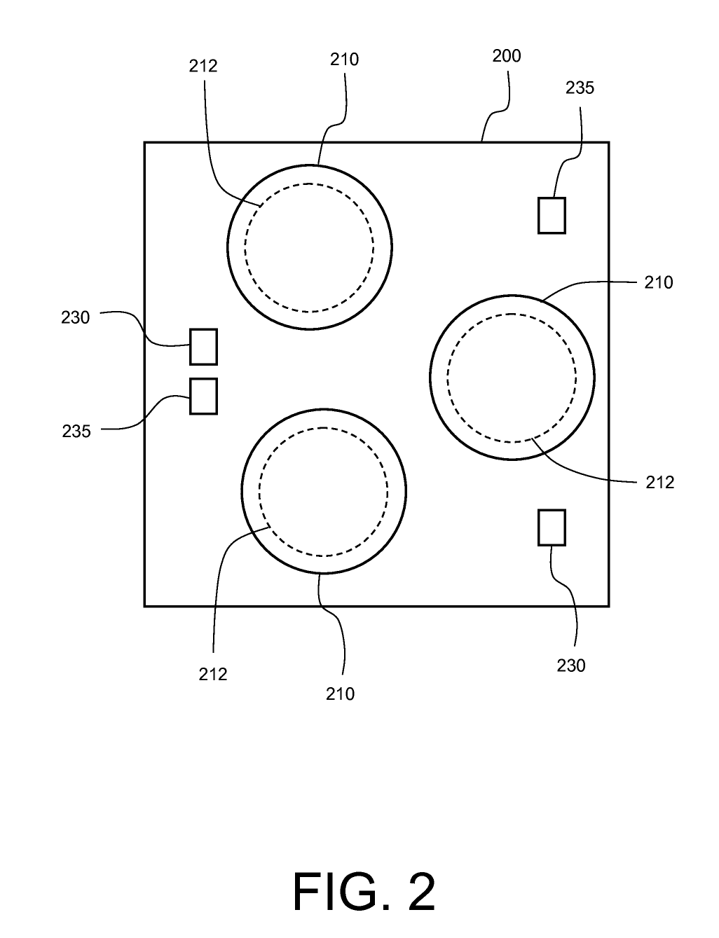

FIG. 2 shows one embodiment of a semiconductor die 200 including a plurality of acoustic devices 210. Semiconductor die also includes first electrode pads 230 connected to first electrodes of acoustic devices 210, and second electrode pads 235 connected to second electrodes of acoustic devices 210. In a beneficial embodiment, acoustic devices 210 are MEMS acoustic transducers each having a diaphragm or membrane structure. Through-holes 212 are provided beneath the diaphragms of acoustic devices 210.

For illustration purposes only, in one embodiment semiconductor die 200 has dimensions of approximately 2 mm on each side, the diaphragms of acoustic devices 210 each have a diameter of 525-779 μm, and through hole 212 has a diameter of 395-649 μm.

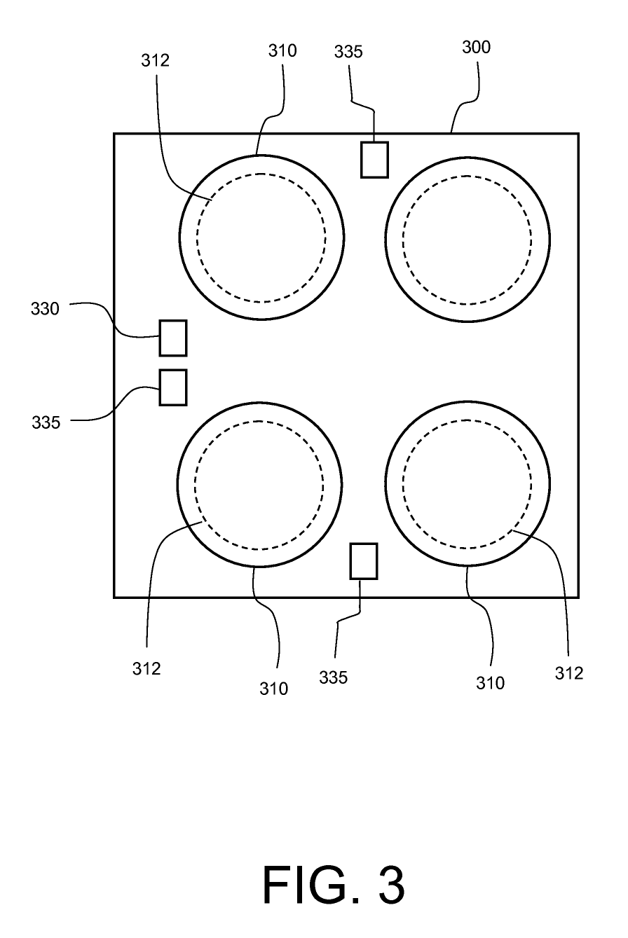

FIG. 3 shows another embodiment of a semiconductor die 300 including a plurality of acoustic devices 310. Semiconductor die also includes first electrode pads 330 connected to first electrodes of acoustic devices 310, and second electrode pads 335 connected to second electrodes of acoustic devices 310. In a beneficial embodiment, acoustic devices 310 are MEMS acoustic transducers each having a diaphragm or membrane structure. Through-holes 312 are provided beneath the diaphragms of acoustic devices 310.

For illustration purposes only, in one embodiment semiconductor die 300 has dimensions of approximately 2 mm on each side, the diaphragms of acoustic devices 310 each have a diameter of 525-779 μm, and through hole 112 has a diameter of 395-649 μm.

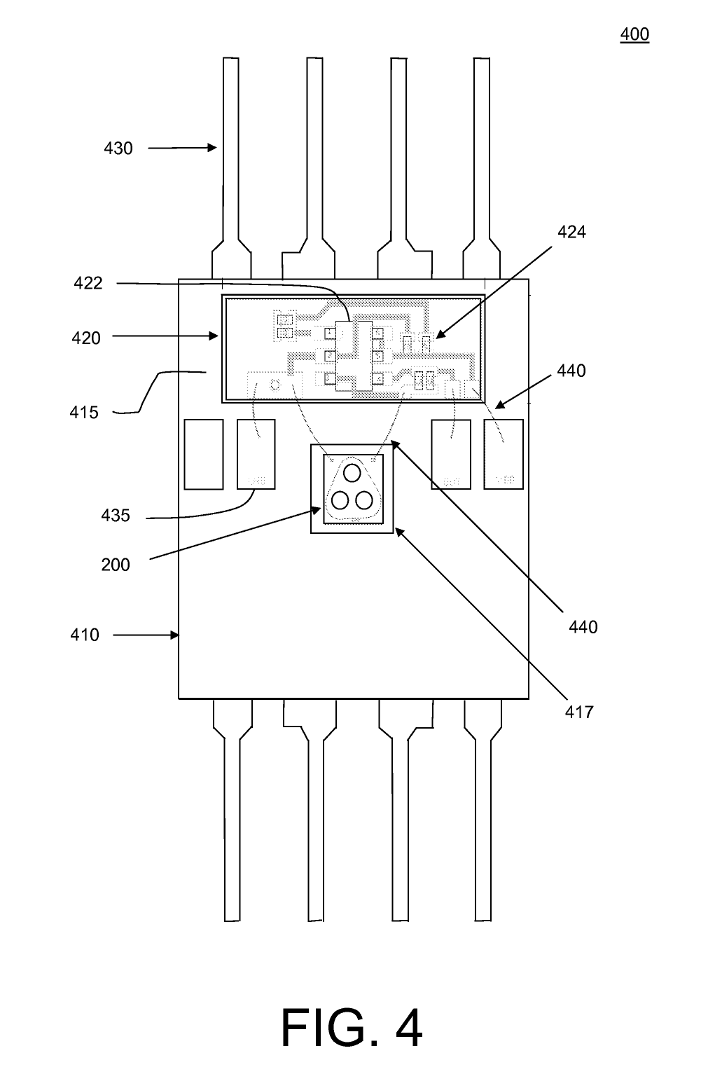

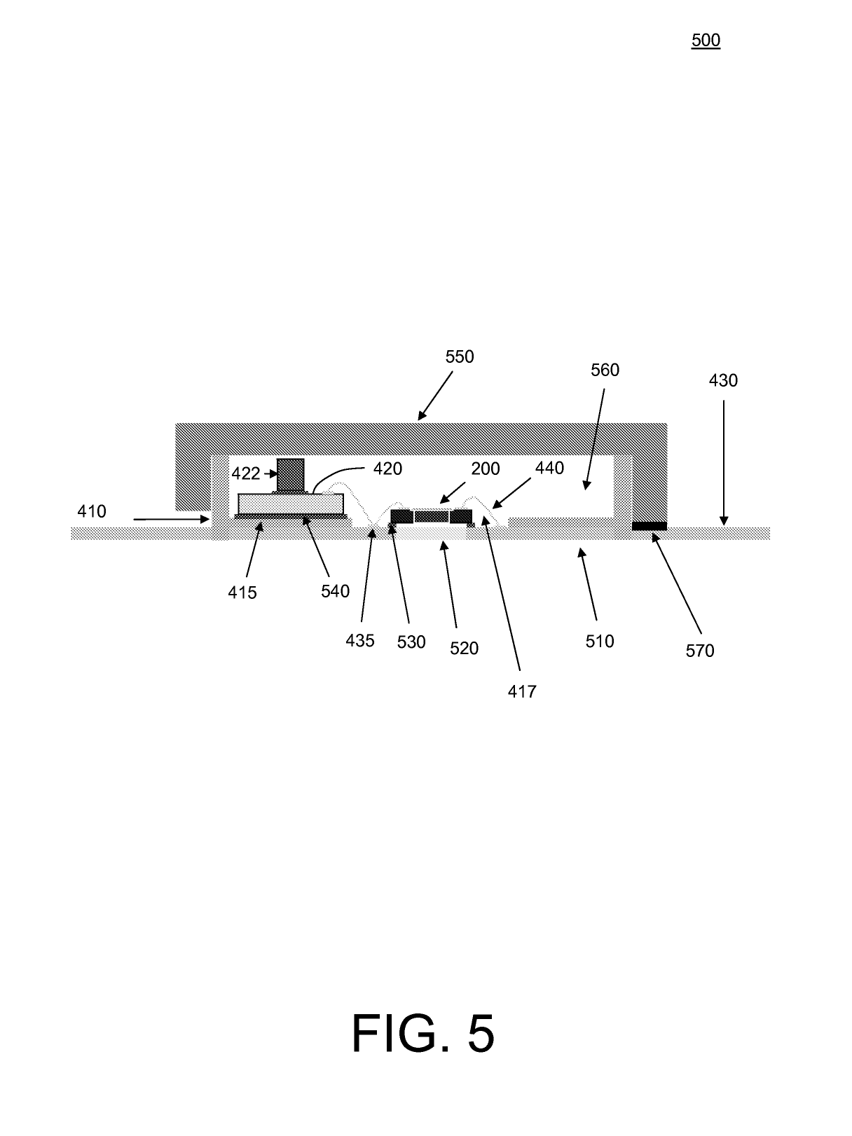

FIG. 4 shows a top cutaway view, and FIG. 5 shows a side cutaway view, of a portion of one embodiment of a packaged acoustic device 400. Packaged acoustic device 400 includes a housing 410, a plurality of terminal leads 430 integrally connected to a lead frame 510, and a semiconductor die 200 having one or more (e.g., three) acoustic transducers. Of course in other embodiments, other semiconductor dies, for example semiconductor dies 100 or 300, having different numbers and/or configurations of acoustic transducers could be employed instead of semiconductor die 200.

Packaged acoustic device 400 also includes a substrate 420 which includes one or more electronic devices (e.g., an amplifier) for operating with the acoustic transducer(s) of semiconductor die 200. However, it should be understood that in some embodiments, the substrate and the electronic devices may be omitted from the packaged acoustic device. Accordingly, packaged acoustic device 400 may be seen to represent a general embodiment that includes various features that may or may not be included in other embodiments.

Lead frame 510 and terminal leads 430 are formed from an electrically conductive material, such as various metals and metal alloys, including copper, nickel, aluminum, brass, copper/zinc alloys, and the like, or a combination thereof, for example. The material may be etched to form separate conductors and terminal leads 430, as well as other features, such as aperture 520 and pads 435. Lead frame 510 may also be plated for wirebonding, for example, using an optimized plating material, such as nickel and/or gold, to permit gold or aluminum wirebond attachment.

As shown in FIG. 5, lead frame 510 includes an aperture 520 passing therethrough located in a central region of lead frame 510. Semiconductor die 200 is disposed above aperture 520 so as to facilitate communication of acoustic waves or signals between the acoustic transducer(s) of semiconductor die 200 and an exterior of packaged acoustic device 400.

Housing 410 further includes a base portion 415. The base portion 415 of housing 410 has an aperture 417 aligned with aperture 520.

In some embodiments, semiconductor die 200 is mounted on lead frame 510, for example by an adhesive 530 such as an epoxy. In other embodiments, particularly where aperture 417 is the same or nearly the same size as aperture 520, semiconductor die 200 is mounted or attached to a portion of housing 410 that surrounds aperture 417. Other arrangements are possible.

In some embodiments, housing 410 is formed from a non-conductive material, such as various plastics or polymers, including liquid crystal polymer (LCP), polybutylene terephthalate (PBT), polypropylene (PP), polyphthalamide (PPA), and the like, for example.

In a beneficial embodiment, housing 410 includes an acoustic horn (not shown in FIGS. 4 and 5) on an opposite side of lead frame 510 from semiconductor die 200, for coupling acoustic waves between the ambient air atmosphere and the acoustic transducer(s) of semiconductor die 200.

Substrate 420 is mounted on base portion 415 of housing 410, for example by means of an adhesive 540 such as an epoxy. In the illustrated embodiment, substrate 420 is a printed circuit board. Beneficially, substrate 420 may be a ceramic or alumina ceramic substrate with electrically conductive pads and traces formed thereon, for example by a thick film printing metallization process.

Substrate 420 has mounted thereon an amplifier, which may be an operational amplifier. In the illustrated embodiment, the amplifier includes an integrated circuit device 422 with active elements, and one or more external components 424 (e.g., resistor(s), capacitor(s), etc.) for setting at least one operating parameters (e.g., gain, bandwidth, etc.) of the amplifier, and/or for filtering one or more supply voltages provided to the amplifier. In the illustrated example, integrated circuit device 422 is a packaged semiconductor die with leads connected to metal traces on substrate 420. However in other embodiments, integrated circuit device 422 may comprise an unpackaged semiconductor die. In some embodiments, the parameter-setting resistor(s)/capacitor(s) may be incorporated within the semiconductor die.

Bond wires 440 electrically and operationally connect the amplifier to the acoustic transducer(s) of semiconductor die 200, directly and/or via intermediate connections to pads 435 of lead frame 510. Also, bond wires 440 connect the amplifier of substrate 420 to one or more supply voltages, including an electrical ground, supplied via terminal leads 430. Such connections may be made via one or more pads 435.

Again, as noted above, it should be appreciated that some embodiments do not include substrate 420 or its associated electronics within the packaged acoustic device.

As shown in FIG. 5, packaged acoustic device 400 further includes a lid or cap 550. Lid 550 is attached to the combined lead frame 510 and housing 410. As shown in FIG. 5, lid 550 fits over lead frame 510 and housing 410, and together with base portion 415 of housing 410 defines a cavity 560. Semiconductor die 200 including its acoustic transducer(s), and the amplifier including integrated circuit device 422 (in embodiments that include these components), are both disposed within cavity 560. Terminal leads 430 extend from the encasement formed by lead frame 510, lid 550, and base portion 415 of housing 410, to enable electrical contact between external circuits and the amplifier and/or acoustic transducer(s) of packaged acoustic device 400. In one embodiment, lid 550 is mechanically attached to base portion 415 of housing 410 by press fitting, for example. Alternatively or in addition, lid 550 may be attached to base portion 415 of housing 410 using an epoxy adhesive, for example, creating a hermetically sealed environment. Of course, other means of attachment, such as soldering, clamping, and the like, may be incorporated without departing from the scope of the present teachings.

In a beneficial arrangement, lid 550 provides shielding of acoustic transducer device(s) of semiconductor die 200 from exposure to externally-generated electromagnetic radiation that can interfere with the proper operation of the acoustic transducer, i.e., shielding from electromagnetic interference (EMI). In some embodiments, one of the terminal leads 430 is a ground lead that is configured to be connected to an electrical ground for the packaged acoustic device 400, and lid 550 is formed of an electrically conductive material, such as a metal, and is directly connected to the ground lead 430, for example by conductive epoxy 570 as shown in FIG. 5. Other means of connecting lid 550 to the ground lead 430, such as soldering, are possible

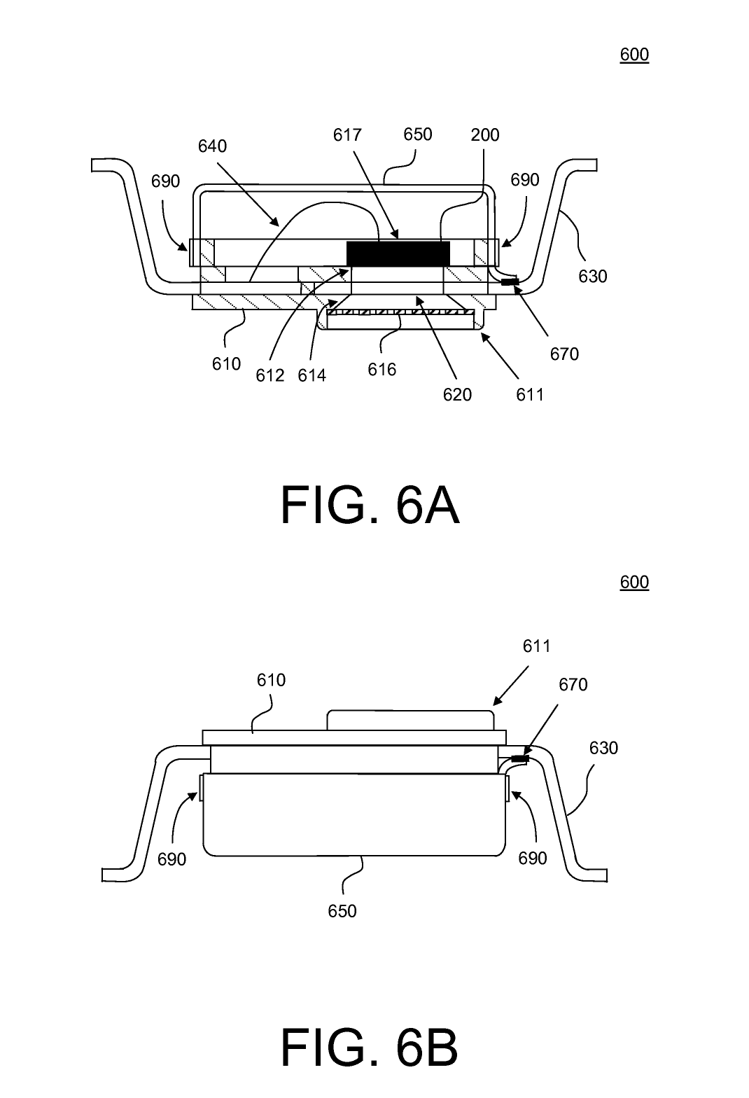

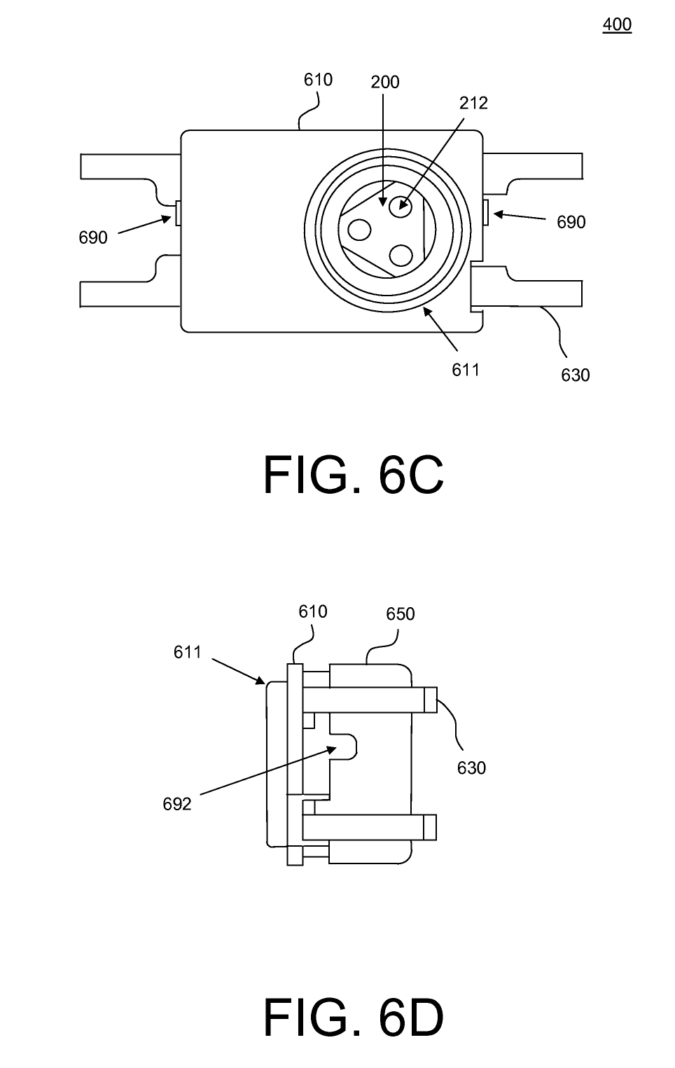

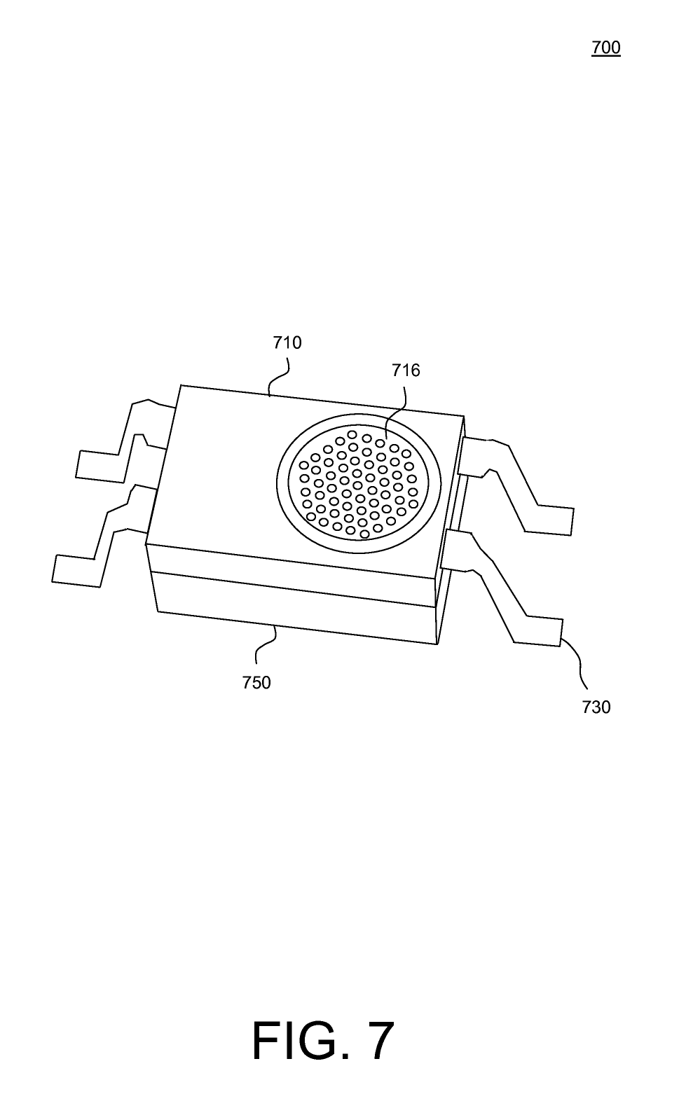

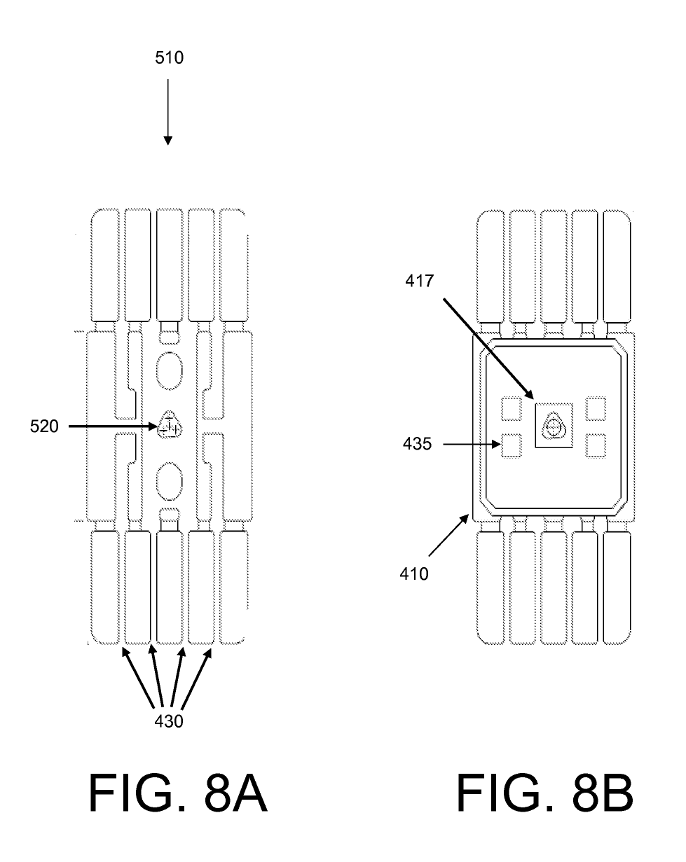

FIG. 6A shows a side cutaway view of another embodiment of a packaged acoustic device 600 that illustrates EMI shielding of the acoustic transducer. FIG. 6B shows a first side view of the packaged acoustic device of FIG. 6A, FIG. 6C shows a top view of the packaged acoustic device of FIGS. 6A-B, and FIG. 6D shows a second side view of the packaged acoustic device of FIGS. 6A-C.

Packaged acoustic device 600 includes a housing 610, a plurality of terminal leads 630, a semiconductor die 200 having one or more (e.g., three) acoustic transducers, and an electrically-conductive lid 650. Of course in other embodiments, other semiconductor dies, for example semiconductor dies 100 or 300, having different numbers and/or configurations of acoustic transducers could be employed instead of semiconductor die 200.

Terminal leads 630 and a lead frame to which they are attached are formed from an electrically conductive material, such as various metals and metal alloys, including copper, nickel, aluminum, brass, copper/zinc alloys, and the like, or a combination thereof, for example. The material may be etched to form separate conductors and terminal leads 630, as well as other features, such as aperture 620. The lead frame may also be plated for wirebonding, for example, using an optimized plating material, such as nickel and/or gold, to permit gold or aluminum wirebond attachment.

As shown in FIG. 6A, the lead frame includes an aperture 620 passing therethrough located in a central region of the lead frame. Semiconductor die 200 is disposed above aperture 620 so as to facilitate communication of acoustic waves or signals between the acoustic transducer(s) of semiconductor die 200 and an exterior of packaged acoustic device 400.

Housing 610 further includes a base portion having an aperture 617 aligned with aperture 620 in the lead frame.

In some embodiments, semiconductor die 200 is mounted on the lead frame, for example by an adhesive such as an epoxy. In other embodiments, particularly where aperture 617 is the same or nearly the same size as aperture 620, semiconductor die 200 is mounted or attached to a portion of housing 610 that surrounds aperture 617. Other arrangements are possible.

In some embodiments, housing 610 is formed from a non-conductive material, such as various plastics or polymers, including liquid crystal polymer (LCP), polybutylene terephthalate (PBT), polypropylene (PP), polyphthalamide (PPA), and the like, for example.

As shown in FIG. 6A, packaged acoustic device 600 further includes a lid or cap 650. Lid 650 is attached to the combined lead frame and housing 610. Lid 650 fits over housing 610, and together with housing 610 defines a cavity in which is disposed semiconductor die 200 including its acoustic transducer(s). Terminal leads 630 extend from the encasement formed by the combination of the lead frame, lid 650, and housing 610, to enable electrical contact between external circuits and the acoustic transducer(s) of packaged acoustic device 600. In device 600, lid 650 is mechanically attached to housing 610 by engaging each of the protruding members 690 with a feature 692 (e.g., a slot or groove) in lid 650 as shown in FIG. 6D. Of course, other means of attaching the lid to the housing may be employed without departing from the scope of the present teachings.

In a beneficial arrangement, lid 650 provides shielding of acoustic transducer device(s) of semiconductor die 200 from exposure to externally-generated electromagnetic radiation that can interfere with the proper operation of the acoustic transducer, i.e., shielding from electromagnetic interference (EMI). In some embodiments, one of the terminal leads 630 is a ground lead that is configured to be connected to an electrical ground for the packaged acoustic device 600. Lid 650 is formed of an electrically conductive material, such as a metal, and as shown in FIG. 6, includes an extending portion that is directly connected to the ground lead 630, for example by conductive epoxy 670. Other means of connecting lid 650 to the ground lead 630, such as soldering, are possible.

In a beneficial embodiment, housing 610 includes an acoustic horn 611 provided on an opposite side of the lead frame from semiconductor die 200 for coupling acoustic waves between the ambient air atmosphere and the acoustic transducer(s) of semiconductor die 200. Generally, horns may be used to amplify acoustic signals, making them louder, as indicated by the incorporation of horns in various musical instruments and early hearing aids, for example. Horns may also be used to manipulate radiation patterns of acoustic emitters, generally referred to as beam forming or beam shaping, thus affecting dispersion of the acoustic signals. In addition, horns may provide impedance matching, rendering an acoustic transducer more compatible with the medium through which the acoustic signals travel.

In the depicted embodiment, acoustic horn 611 is integral with housing 610 and comprises a protruding portion that extends from the base portion of housing 610 along a center axis in a direction substantially perpendicular to the lead frame. In a representative embodiment, housing 610 including acoustic horn 611 is formed from plastic transfer molded to the lead frame, as discussed below.

In one embodiment, acoustic horn 611 has a flared cross-sectional shape (e.g., hyperbolic or exponential), such that an inner dimension of acoustic horn 611 extends outwardly from an inner aperture or throat 612 to a flared outer aperture or mouth 614. For example, the throat 612 may be circular with a diameter of about 2 mm and the mouth 614 may likewise be circular with a diameter of about 8 mm. However, the sizes and shapes of acoustic horn 611 and corresponding throat 612 and mouth 614, as well as the respective configurations of the base portion and the protruding portion of housing 610 may vary to provide unique benefits for any particular situation or to meet application specific design requirements of various implementations. For example, the cross-sectional shape of the protruding portion of acoustic horn 611 may be substantially conical, tubular, rectangular or trapezoidal, without departing from the scope of the present teachings.

Acoustic horn 610 may be molded in the shape depicted, for example, in FIG. 6, using transfer molding or other molding techniques, to support different environmental and operating conditions.

Device 600 further includes a protective mesh or barrier screen 616 that covers mouth 614 of acoustic horn 611. Beneficially, screen 616 may include a pattern of apertures for communicating acoustic signals between the acoustic transducer(s) of semiconductor die 200 and the exterior of packaged acoustic device 600. For example, each of the apertures of screen 616 may be substantially smaller than the size of aperture 620 in the lead frame. Screen 616 may include acoustically transparent solid material to allow acoustic signals to exit and/or enter aperture 620, but limiting debris, contaminants and/or moisture that can enter aperture 620. In an embodiment, screen 616 is positioned directly in mouth 612 of the protruding portion of acoustic horn 610. Screen 616 may be applied after assembling the packaged acoustic device 400, including attachment of lid 650.

In some embodiments, screen 616 provides EMI shielding for the acoustic transducer(s) of semiconductor die 200. In particular, screen 616 may comprise an electrically conductive material, for example a metal. In that case, in some embodiments screen 616 may be electrically connected to the ground lead 630 of device 600, for example through lid 650, or by some other connection.

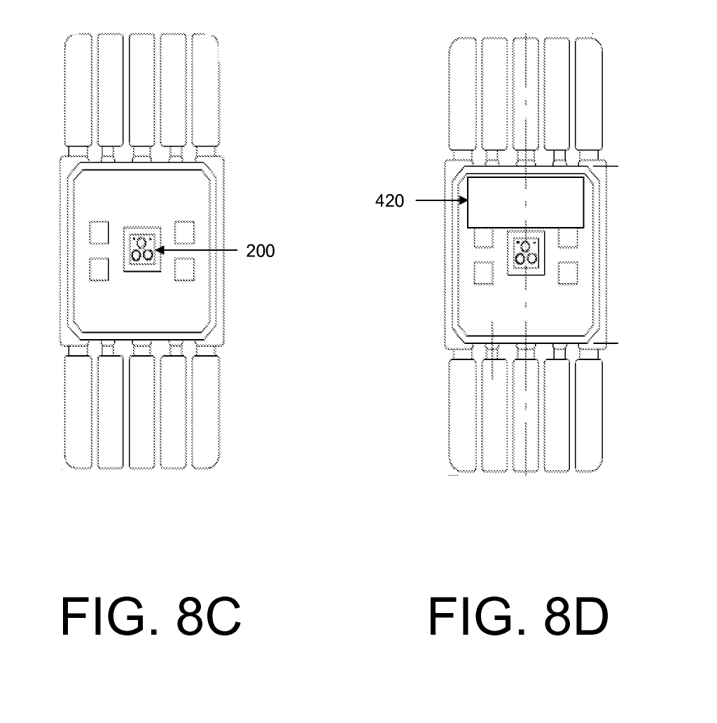

FIG. 7 shows a perspective view of one embodiment of a packaged acoustic device 700. Device 700 includes housing 710, screen 716, electrically-conductive lid 750, and electrically conductive leads 730. Electrically conductive leads 730 include a ground lead 730 that is connected to electrically-conductive lid 750 to provide EMI shielding for one or more acoustic transducer(s) disposed within a cavity defined by housing 710 and electrically-conductive lid 750. In some embodiments, screen 716 also provides additional EMI shielding for the acoustic transducer(s).

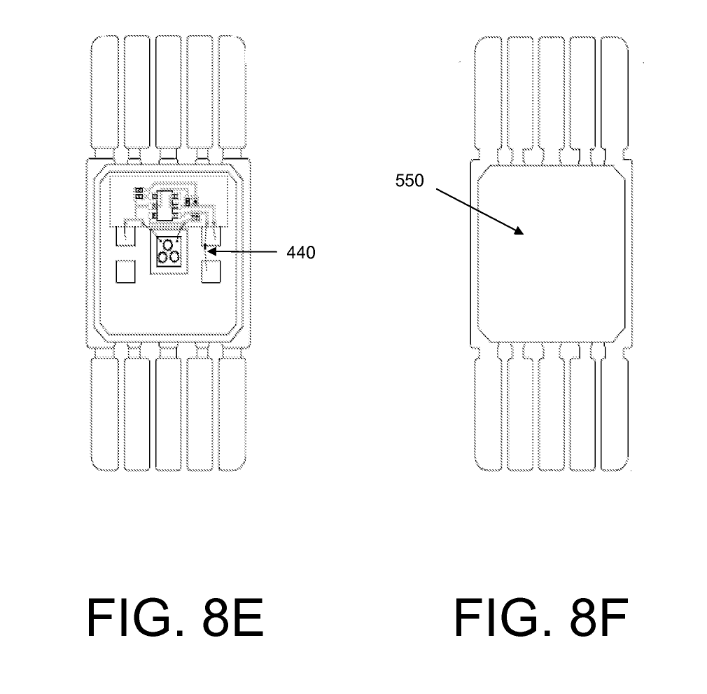

FIGS. 8A-F illustrate various stages in one embodiment of a process of manufacturing packaged acoustic device 400.

FIG. 8A shows lead frame 510 including electrical leads 430 and aperture 520 provided in a central region thereof. As discussed above, lead frame 510 may be plated for wirebonding, for example, using an optimized plating material, such as nickel and/or gold, to permit gold or aluminum wirebond attachment.

FIG. 8B shows a next intermediate product where housing 410 has been attached to lead frame 510.

In an example embodiment, a molding operation is performed on lead frame 510. The molding operation includes placing lead frame 510 in a transfer mold previously formed to define the shape of housing 410, including for example base portion 415 and acoustic horn 610. A polymer, e.g., LCP, PBT, PP, or PPA, is then transfer molded, for example, to encapsulate lead frame 510 and to simultaneously form housing 410, for example including an acoustic horn that is on the bottom of device 400 in the views of FIGS. 8A-F, and therefore not shown in these drawings. The polymer is typically a solid at room temperature, and melted prior to transfer to the mold. The shape of the acoustic horn is defined by the shape of the machined transfer mold. The cooled (after melting) mold plastic will assume the horn shape within the transfer mold. Accordingly, housing 410, including for example a plastic acoustic horn, is integrally formed to surround lead frame 510 during the molding operation.

FIG. 8C shows a next intermediate product where semiconductor die 200 including acoustic transducer(s) are mounted on lead frame 510 above aperture 520, for example by an adhesive bond.

FIG. 8D shows a next intermediate product where substrate 420 including the amplifier (e.g., an operational amplifier), is mounted on base portion 415 of housing 410, for example by an adhesive bond. In some embodiments as mentioned above, substrate 420 and its associated circuitry may be omitted.

FIG. 8E shows a next intermediate product where one or more wire bonds 440 are applied to provide connections between the amplifier and/or acoustic transducer(s) of semiconductor die 220 and/or pads 435 of lead frame 510.

FIG. 8F shows a next intermediate product where lid 550 has been applied to housing 410 and lead frame 510. As described above, lid 550 is directly connected (e.g., via conductive epoxy) to one of the leads 430 which is a ground lead 430 for device 400 to provide EMI shielding of the acoustic transducer(s) of semiconductor die 200.

Although not specifically shown in FIGS. 8A-F, in a step somewhere in the manufacturing process lead frame 510 and terminal leads 430 are disconnected from a supporting lead frame structure.

While example embodiments are disclosed herein, one of ordinary skill in the art appreciates that many variations that are in accordance with the present teachings are possible that remain within the scope of the appended claims. The embodiments therefore are not to be restricted except within the scope of the appended claims.

1. A device, comprising:
an electrically conductive lead frame having an aperture therethrough, the electrically conductive lead frame including a plurality of leads including at least one ground lead configured to be connected to an electrical ground;
a semiconductor die including at least one acoustic transducer disposed above the aperture in the electrically conductive lead frame, the at least one acoustic transducer being configured to convert between acoustic energy and an electrical signal;
an acoustic horn integrally connected to the lead frame, the horn extending from the lead frame and comprising a throat positioned adjacent to the acoustic transducer and a mouth opening at an opposite end of the acoustic horn from the throat;
an electrically conductive and acoustically transmissive screen disposed over the mouth of the acoustic horn; and
an electrically conductive lid configured together with the base portion of the housing to define a cavity, wherein the acoustic transducer is positioned within the cavity, and wherein the electrically conductive lid is directly connected to the ground lead.

2. The device of claim 1, wherein the semiconductor die includes a through-hole aligned with the aperture in the lead frame and wherein the acoustic transducer includes a diaphragm disposed above the through-hole in the semiconductor die.

3. The device of claim 1, further including at least one bond wire connected between a pad on the semiconductor die and at least one lead of the lead frame.

4. The device of claim 1, wherein the acoustic transducer comprises a micro electro-mechanical system (MEMS) transducer.

5. The device of claim 1, wherein the cavity is hermetically sealed.

6. The device of claim 1, wherein the acoustic horn comprises plastic transfer molded through a portion of the lead frame and extending from the lead frame to the mouth of the horn.

7. The device of claim 1, further comprising:
a substrate mounted on a base portion of the acoustic horn; and
an amplifier mounted on the substrate and electrically connected to the acoustic transducer.

8. The device of claim 1, wherein the electrically conductive lid is connected to the ground lead.

9. A device, comprising:
a housing structure including having a base portion integrated with a plurality of electrically conductive leads including at least one ground lead, the housing structure including an aperture extending through a first side thereof;
an electrically conductive lid configured together with the housing structure to define a cavity therein; and
at least one acoustic transducer disposed within the cavity and disposed above the aperture in the housing structure,
wherein the electrically conductive lid is directly connected to the ground lead.

10. The device of claim 9, further comprising an amplifier disposed within the cavity and electrically connected to the acoustic transducer.

11. The device of claim 9, wherein the housing structure includes an acoustic horn having a first opening at an end where the base portion is connected to the electrically conductive leads, the first opening surrounding the aperture in the housing structure, and having a second opening at an opposite end of the acoustic horn from the first opening, wherein a diameter of the second opening is greater than a diameter of the first opening.

12. The device of claim 11, further comprising an electrically conductive and acoustically transmissive screen disposed over the mouth of the acoustic horn.

13. The device of claim 9, wherein the acoustic device includes a diaphragm disposed above a through-hole in a semiconductor substrate, wherein the through-hole is aligned with the aperture in the housing structure.

14. The device of claim 13, further including at least one bond wire connected between a pad on the semiconductor die and at least one lead of the lead frame.

15. The device of claim 9, wherein the acoustic transducer comprises a micro electro-mechanical system (MEMS) transducer.

16. The device of claim 9, wherein the cavity is hermetically sealed.

17. A device, comprising:
a housing structure;
a lid configured together with the housing structure to define a cavity therein; and
at least one acoustic transducer disposed within the cavity,
wherein the lid shields the at least one acoustic transducer from exposure to electromagnetic interference from electromagnetic radiation originating outside the device.

18. The device of claim 17, wherein the housing structure includes a ground lead connected to the lid.

19. The device of claim 17, further comprising:
an acoustic horn communicating acoustic energy between the acoustic transducer and an exterior of the device; and
an electrically conductive and acoustically transmissive screen disposed over the mouth of the acoustic horn.

20. The device of claim 17, further comprising an amplifier disposed within the cavity and electrically connected to the acoustic transducer.
